(19) United States
(12) Patent Application Publication
(10) Pub. No.: US 2026/0334087 A1
(43) Pub. Date: Oct. 22, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Hui-Lin Wang, Taipei City (TW); Chen-Yi Weng, New Taipei City (TW); Che-Wei Chang, Taichung City (TW); Ching-Hua Hsu, Kaohsiung City (TW)

(73) Assignee: UNITED MICROELECTRONICS CORP., Hsin-Chu City (TW)

(21) Appl. No.: 19/213,994

(22) Filed: May 20, 2025

(30) Foreign Application Priority Data
Apr. 21, 2025 (TW) 114114971

(51) Int. Cl. H10N 50/10; H01L 23/528; H10B 61/00; H10N 50/01; H10N 50/80

(52) U.S. Cl. CPC H10N 50/10; H10B 61/10; H10N 50/01; H10N 50/80; H10W 20/435

(57) ABSTRACT

A method for fabricating a semiconductor device includes the steps of first forming a first inter-metal dielectric (IMD) layer on a substrate, forming a metal interconnection in the first IMD layer, forming a stop layer on the first IMD layer, patterning to stop layer to form an opening, forming a bottom electrode (BE) in the opening, forming a magnetic tunneling junction (MTJ) stack on the BE, and patterning the MTJ stack to form a MTJ.

### BACKGROUND OF THE INVENTION

### 1. Field of the Invention

The invention relates to a semiconductor device and method for fabricating the same, and more particularly to a magnetoresistive random access memory (MRAM) and method for fabricating the same.

### 2. Description of the Prior Art

Magnetoresistance (MR) effect has been known as a kind of effect caused by altering the resistance of a material through variation of outside magnetic field. The physical definition of such effect is defined as a variation in resistance obtained by dividing a difference in resistance under no magnetic interference by the original resistance. Currently, MR effect has been successfully utilized in production of hard disks thereby having important commercial values. Moreover, the characterization of utilizing GMR materials to generate different resistance under different magnetized states could also be used to fabricate MRAM devices, which typically has the advantage of keeping stored data even when the device is not connected to an electrical source.

The aforementioned MR effect has also been used in magnetic field sensor areas including but not limited to for example electronic compass components used in global positioning system (GPS) of cellular phones for providing information regarding moving location to users. Currently, various magnetic field sensor technologies such as anisotropic magnetoresistance (AMR) sensors, GMR sensors, magnetic tunneling junction (MTJ) sensors have been widely developed in the market. Nevertheless, most of these products still pose numerous shortcomings such as high chip area, high cost, high power consumption, limited sensibility, and easily affected by temperature variation and how to come up with an improved device to resolve these issues has become an important task in this field.

### SUMMARY OF THE INVENTION

According to an embodiment of the present invention, a method for fabricating a semiconductor device includes the steps of first forming a first inter-metal dielectric (IMD) layer on a substrate, forming a metal interconnection in the first IMD layer, forming a stop layer on the first IMD layer, patterning to stop layer to form an opening, forming a bottom electrode (BE) in the opening, forming a magnetic tunneling junction (MTJ) stack on the BE, and patterning the MTJ stack to form a MTJ.

According to another aspect of the present invention, a semiconductor device includes a first inter-metal dielectric (IMD) layer on a substrate, a metal interconnection in the first IMD layer, a bottom electrode (BE) on the metal interconnection, a stop layer on sidewalls of the BE, and a magnetic tunneling junction (MTJ) on the BE and the stop layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for fabricating a MRAM device according to an embodiment of the present invention.

FIGS. 8-12 illustrate a method for fabricating a MRAM device according to an embodiment of the present invention.

### DETAILED DESCRIPTION

Referring to FIGS. 1-7, FIGS. 1-7 illustrate a method for fabricating a semiconductor device, or more specifically a MRAM device according to an embodiment of the present invention. As shown in FIG. 1, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a MTJ region 14 and a logic region (not shown) are defined on the substrate 12.

Active devices such as metal-oxide semiconductor (MOS) transistors, passive devices, conductive layers, and interlayer dielectric (ILD) layer 16 could also be formed on top of the substrate 12. More specifically, planar MOS transistors or non-planar (such as FinFETs) MOS transistors could be formed on the substrate 12, in which the MOS transistors could include transistor elements such as gate structures (for example metal gates) and source/drain region, spacer, epitaxial layer, and contact etch stop layer (CESL). The ILD layer 16 could be formed on the substrate 12 to cover the MOS transistors, and a plurality of contact plugs could be formed in the ILD layer 16 to electrically connect to the gate structure and/or source/drain region of MOS transistors. Since the fabrication of planar or non-planar transistors and ILD layer is well known to those skilled in the art, the details of which are not explained herein for the sake of brevity.

Next, metal interconnect structures 18, 20 are sequentially formed on the ILD layer 16 to electrically connect the aforementioned contact plugs, in which the metal interconnect structure 18 includes an inter-metal dielectric (IMD) layer 22 and metal interconnections 24 embedded in the IMD layer 22, and the metal interconnect structure 20 includes a stop layer 26, an IMD layer 28, and metal interconnections 30, 32 embedded in the stop layer 26 and the IMD layer 28.

In this embodiment, each of the metal interconnections 24 from the metal interconnect structure 18 preferably includes a trench conductor and each of the metal interconnections 30, 32 from the metal interconnect structure 20 includes a via conductor. Preferably, each of the metal interconnections 24, 30, 32 from the metal interconnect structures 18, 20 could be embedded within the IMD layers 22, 28 and/or stop layer 26 according to a single damascene process or dual damascene process. For instance, each of the metal interconnections 24, 30, 32 could further include a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In this embodiment, the metal layers 36 in the metal interconnections 24 are preferably made of copper, the metal layers 36 in the metal interconnections 30, 32 are preferably made of tungsten or copper, the IMD layers 22, 28 are preferably made of silicon oxide or ultra low-k (ULK) dielectric layer, and the stop layers 26 is preferably made of nitrogen doped carbide (NDC), silicon nitride, silicon carbon nitride (SiCN), or combination thereof.

Next, a stop layer 74 is formed on the IMD layer 28 to cover the surface of the IMD layer 28 and metal interconnections 30, 32 entirely. Preferably, the stop layer 74 is made of nitrogen doped carbide (NDC), silicon nitride, silicon carbon nitride (SiCN), silicon oxynitride (SiON), or combination thereof.

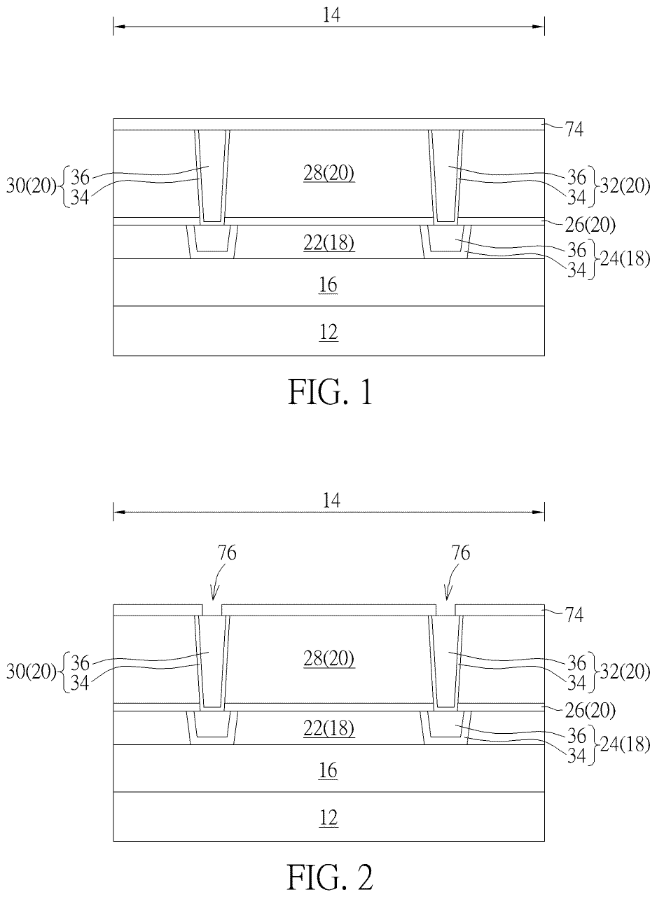

Next, as shown in FIG. 2, a photo-etching process is conducted to pattern the stop layer 74 by using a patterned mask (not shown) such as patterned resist as mask to remove part of the stop layer 74 through etching for forming openings 76 exposing the surface of the metal interconnections 30, 32 but not exposing the surface of the IMD layer 28 adjacent to two sides of the metal interconnections 30, 32. In other words, the width of each of the openings 76 is slightly less than the width of top surface of the metal interconnections 30, 32.

Next, as shown in FIG. 3, a bottom electrode (BE) 42 or BE layer is formed on the stop layer 74 and filling the openings 76 entirely. In this embodiment, the bottom electrode 42 preferably includes metal nitride such as TiN, but not limited thereto.

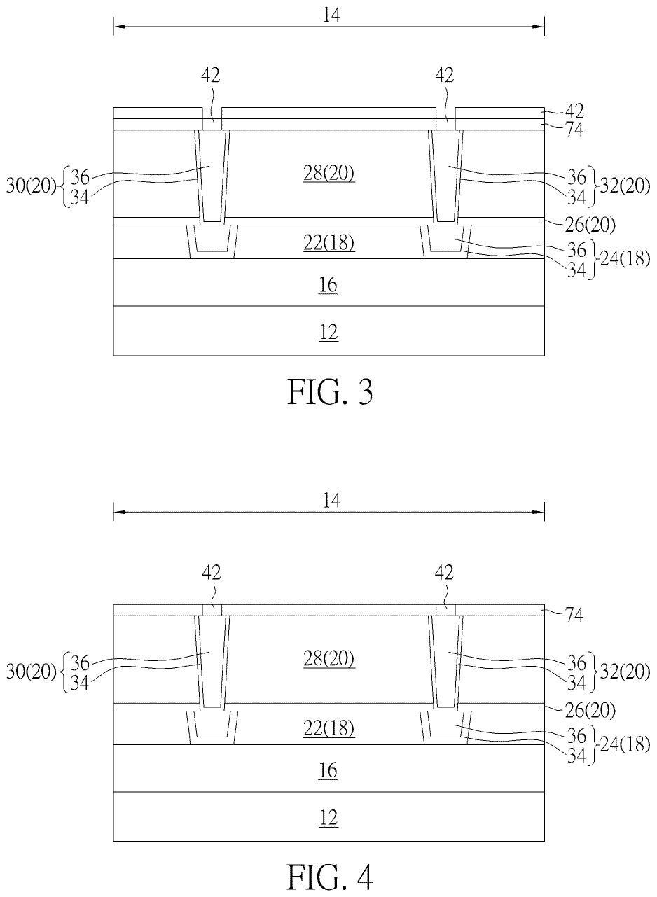

Next, as shown in FIG. 4, a planarizing process such as chemical mechanical polishing (CMP) process is conducted to remove part of the bottom electrode 42 so that the remaining bottom electrode 42 fills each of the openings 76 as the top surface of the bottom electrode 42 is even with the top surface of the stop layer 74 on two adjacent sides. Since the width of the bottom electrode 42 filled into the openings 76 is equal to the width of each of the openings 76, the width of each of the bottom electrode 42 at this stage is also slightly less than the width of the top surface of the metal interconnections 30, 32 underneath.

Next, as shown in FIG. 5, a MTJ stack 38 or stack structure, a top electrode 50, and a patterned mask (not shown) are formed on the metal interconnect structure 20. In this embodiment, the formation of the MTJ stack 38 could be accomplished by sequentially depositing a pinned layer 44, a barrier layer 46, and a free layer 48 on the bottom electrode 42. In this embodiment, the top electrode layer 50 is preferably made of conductive material including but not limited to for example Ta, Pt, Cu, Au, Al, or combination thereof. The pinned layer 44 could be made of ferromagnetic material including but not limited to for example iron, cobalt, nickel, or alloys thereof such as cobalt-iron-boron (CoFeB) or cobalt-iron (CoFe). Moreover, the pinned layer 44 could also be made of antiferromagnetic (AFM) material including but not limited to for example ferromanganese (FeMn), platinum manganese (PtMn), iridium manganese (IrMn), nickel oxide (NiO), or combination thereof, in which the pinned layer 44 is formed to fix or limit the direction of magnetic moment of adjacent layers. The barrier layer 46 could be made of insulating material including but not limited to for example oxides such as aluminum oxide (AlOₓ) or magnesium oxide (MgO). The free layer 48 could be made of ferromagnetic material including but not limited to for example iron, cobalt, nickel, or alloys thereof such as cobalt-iron-boron (CoFeB), in which the magnetized direction of the free layer 48 could be altered freely depending on the influence of outside magnetic field.

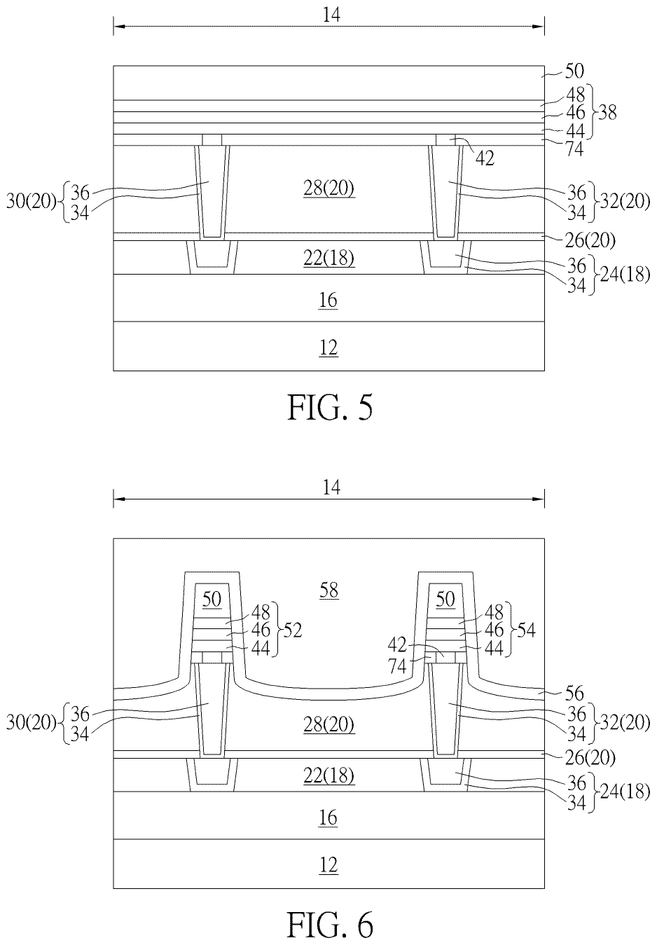

Next, as shown in FIG. 6, one or more etching process is conducted by using the patterned mask as mask to remove part of the top electrode 50, part of the MTJ stack 38, part of the stop layer 74, and part of the IMD layer 28 to form MTJs 52, 54 on the MRAM region 14. It should be noted that a reactive ion etching (RIE) and/or an ion beam etching (IBE) process is conducted to remove part of the top electrode 50, part of the MTJ stack 38, part of the stop layer 74, and part of the IMD layer 28 in this embodiment for forming the MTJs 52, 54 as none of the bottom electrode 42 is removed and sidewalls of the MTJs 52, 54 and stop layer 74 are aligned. Due to the characteristics of the IBE process, the top surface of the remaining IMD layer 28 is slightly lower than the top surface of the metal interconnections 30, 32 after the IBE process and the top surface of the IMD layer 28 also reveals a curve or an arc.

Next, a cap layer 56 is formed on the MTJs 52, 54 while covering the surface of the IMD layer 28 and then an IMD layer 58 is formed to cover the MTJs 52, 54. In this embodiment, the cap layer 56 preferably includes silicon nitride, but could also include other dielectric material including but not limited to for example silicon oxide, silicon oxynitride (SiON), or silicon carbon nitride (SiCN). The IMD layer 58 preferably include an ultra low-k (ULK) dielectric layer including but not limited to for example porous material or silicon oxycarbide (SiOC) or carbon doped silicon oxide (SiOCH).

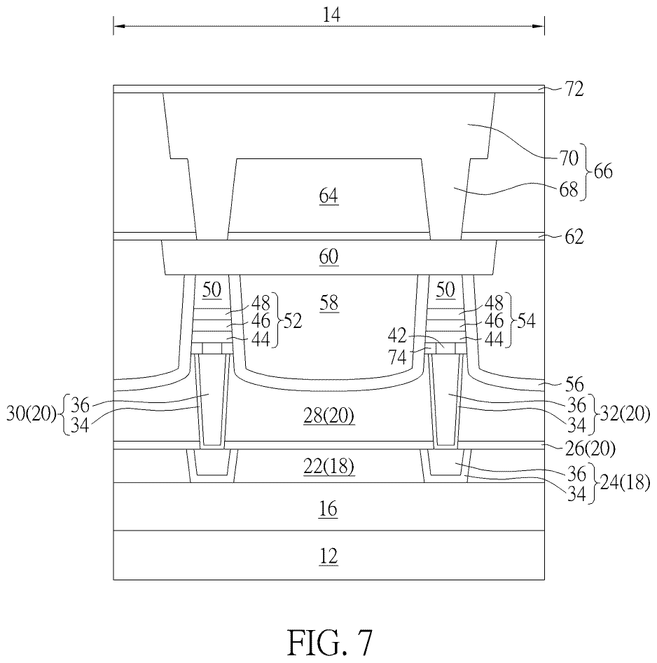

Next, as shown in FIG. 7, a patterned transfer process could be conducted by using a patterned mask (not shown) as mask to remove part of the IMD layer 58 and part of the cap layer 56 for forming a contact hole (not shown) exposing the top electrodes 50 underneath. Next, metal or conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact hole, and then a planarizing process such as CMP process is conducted to remove part of the metals for forming a contact plug or metal interconnection 60 in the contact hole electrically connecting the top electrodes 50 underneath. Next, a stop layer 62 is formed on the IMD layer 58. Preferably, the stop layer 62 is made of nitrogen doped carbide (NDC), silicon nitride, silicon carbon nitride (SiCN), silicon oxynitride (SiON), or combination thereof.

Next, another IMD layer 64 is formed on the surface of the stop layer 62 and one or more photo-etching process is conducted to remove part of the IMD layer 64 and part of the stop layer 62 to form contact holes (not shown). Next, conductive materials are deposited into the contact holes and a planarizing process such as CMP is conducted to form a metal interconnection 66 connecting the top electrode 50 and metal interconnection 60 underneath, and another stop layer 72 is formed on the surface of the metal interconnections 66 thereafter. Similar to the aforementioned metal interconnection 60, the metal interconnections 66 could be embedded within the IMD layer 64 according to a single damascene process or dual damascene process. For instance, the metal interconnection 66 could further include via conductors 68 connecting the metal interconnection 60 underneath and a trench conductor 70 atop the via conductors 68. Moreover, the metal interconnection 66 could further include a barrier layer and a metal layer, in which the barrier layer could be selected from the group consisting of titanium (Ti), titanium nitride (TiN), tantalum (Ta), and tantalum nitride (TaN) and the metal layer could be selected from the group consisting of tungsten (W), copper (Cu), aluminum (Al), titanium aluminide (TiAl), and cobalt tungsten phosphide (CoWP).

In this embodiment, the IMD layer 64 preferably include an ultra low-k (ULK) dielectric layer including but not limited to for example porous material or silicon oxycarbide (SiOC) and the stop layer 72 preferably includes nitrogen doped carbide (NDC), silicon nitride (SiN), silicon carbon nitride (SiCN), or combination thereof and most preferably includes SiN. This completes the fabrication of a semiconductor device according to an embodiment of the present invention.

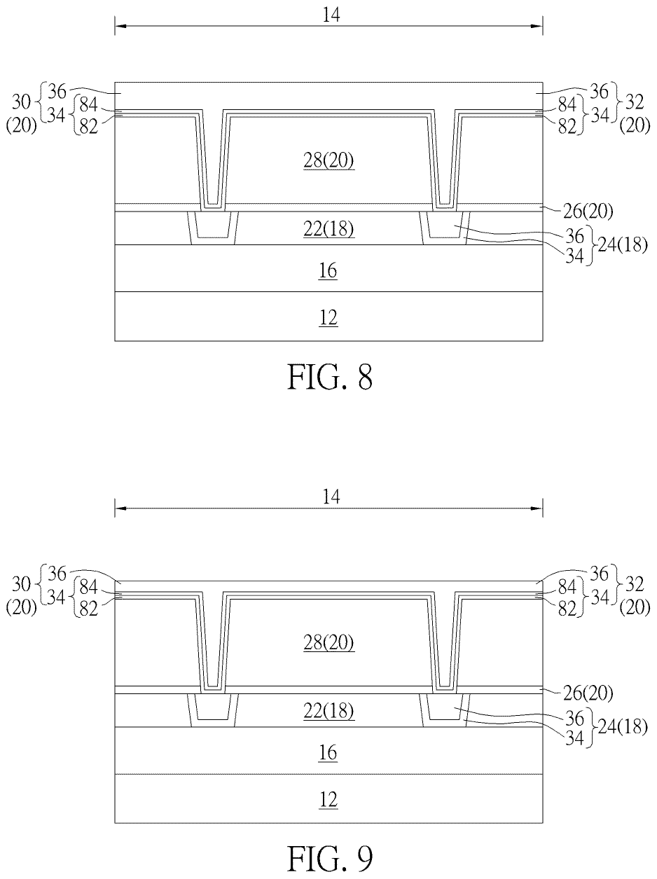

Referring to FIGS. 8-12, FIGS. 8-12 illustrate a method for fabricating a semiconductor device, or more specifically a MRAM device according to an embodiment of the present invention. As shown in FIG. 8, metal interconnect structures 18, 20 are formed on the substrate 12 according to the process conducted in FIG. 1. It should be noted that during the formation of the metal interconnections 30, 32 in the IMD layer 28 as shown in FIG. 1, a photo-etching process is first conducted to remove part of the IMD layer 28 and part of the stop layer 26 to form contact holes (not shown) exposing the metal interconnections 24 underneath, and then at least a barrier layer 34 and a metal layer 36 are deposited into the contact holes. Preferably, the barrier layer 34 is formed on the surface of the IMD layer 28 and sidewalls and bottom surface of the contact holes while the metal layer 36 is formed on the barrier layer 34 and filling the contact holes completely.

In this embodiment, the barrier layer 34 preferably includes a dual-layer structure, in which the lower barrier layer 82 closer and directly contacting the IMD layer 28 preferably includes Ti while the upper barrier layer 84 includes TiN. Nevertheless, according to other embodiment of the present invention, each of the barrier layers 82, 84 could all be selected from the group consisting of titanium (Ti), titanium nitride (TiN), tantalum (Ta), and tantalum nitride (TaN), which is also within the scope of the present invention.

Moreover, even though the barrier layer 34 of this embodiment pertains to be a dual-layer structure made of dual barrier layers 82, 84, according to other embodiment of the present invention the barrier layer 34 could also be a single-layered structure disposed between the IMD layer 28 and the metal layer 36, in which the single-layered barrier layer 34 could also be selected from the group consisting of titanium (Ti), titanium nitride (TiN), tantalum (Ta), and tantalum nitride (TaN). In other words, if the barrier layer 34 were to be a single-layered structure, the bottom surface of the barrier layer 34 made of TiN for instance would directly contact the IMD layer 28 while the top surface of the same barrier layer 34 also made of TiN would directly contact the metal layer 36 made of tungsten above.

Next, as shown in FIG. 9, a planarizing process such as a chemical mechanical polishing (CMP) process is conducted to remove part of the metal layer 36 without exposing and removing any of the barrier layer 34 underneath. In other words, the planarizing process conducted at this stage only removes part of the metal layer 36 so that the overall thickness of the metal layer 36 is lowered. The top surface of the barrier layer 34 however is not exposed at this stage as the top surface of the remaining metal layer 36 is slightly higher than the top surface of the barrier layer 34.

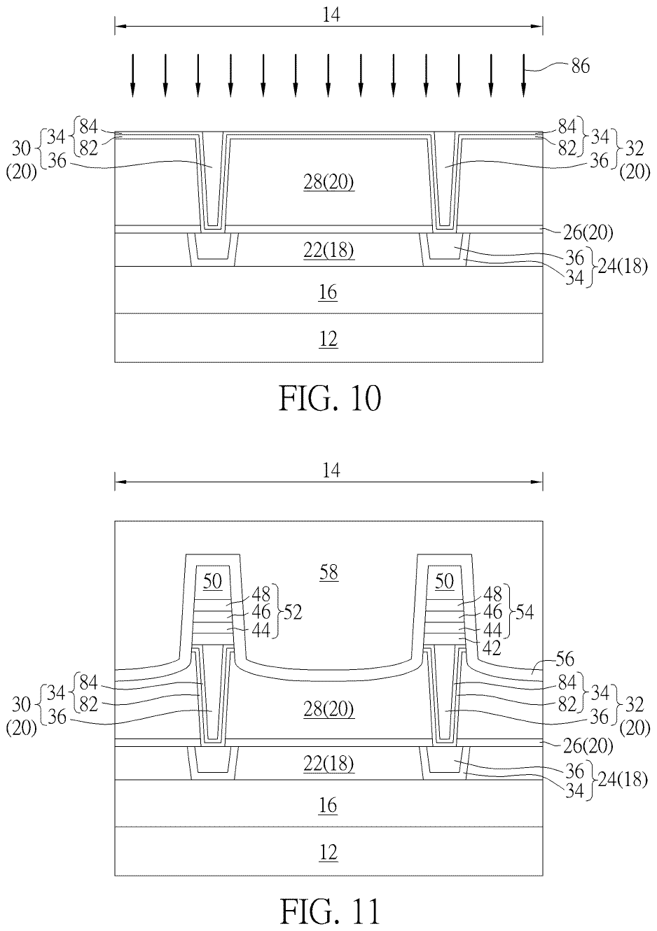

Next, as shown in FIG. 10, an etching back process is conducted to remove part of the metal layer 36 once more and expose the top surface of the barrier layer 34. After the etching back process stops on the surface of the barrier layer 34, the top surface of the remaining metal layer 36 is even with the top surface of the barrier layer 34 as the top surface of both the barrier layer 34 and metal layer 36 is higher than the top surface of the IMD layer 28. Since the etching back process conducted at this stage does not remove any of the barrier layer 34, the top surface of the IMD layer 28 adjacent to two sides of the contact holes is covered with the barrier layer 34 after the etching back process as the top surface of the remaining metal layer 36 is slightly higher than the top surface of the IMD layer 28 and even with the top surface of the barrier layer 34.

Next, as shown in FIG. 11, a bottom electrode 42, a MTJ stack (not shown), a top electrode 50, and a patterned mask (not shown) are formed on the metal interconnect structure 22, and then one or more etching process is conducted by using the patterned mask as mask to remove part of the top electrode 50, part of the MTJ stack, part of the bottom electrode 42, part of the barrier layer 34, and part of the IMD layer 28 for forming MTJs 52, 54 on the MRAM region 14. In this embodiment, the bottom electrode 42 and top electrode 50 could include conductive material including but not limited to for example TiN, Ta, TaN, Pt, Cu, Au, Al, or combination thereof.

Next, a cap layer 56 is formed on the MTJs 52, 54 while covering the surface of the IMD layer 28 and then an IMD layer 58 is formed to cover the MTJs 52, 54. In this embodiment, the cap layer 56 preferably includes silicon nitride, but could also include other dielectric material including but not limited to for example silicon oxide, silicon oxynitride (SiON), or silicon carbon nitride (SiCN). The IMD layer 58 preferably include an ultra low-k (ULK) dielectric layer including but not limited to for example porous material or silicon oxycarbide (SiOC) or carbon doped silicon oxide (SiOCH).

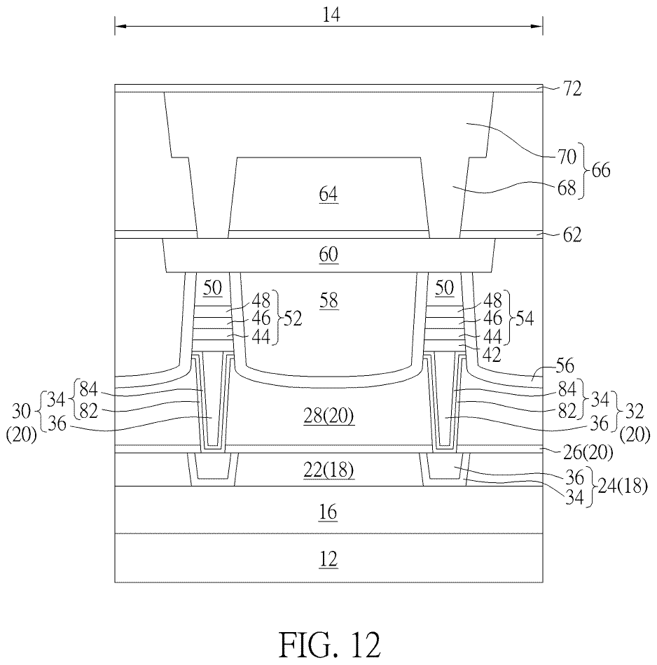

Next, as shown in FIG. 12, a patterned transfer process carried out in FIG. 7 could be conducted by using a patterned mask (not shown) as mask to remove part of the IMD layer 58 and part of the cap layer 56 for forming a contact hole (not shown) exposing the top electrodes 50 underneath. Next, metal or conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact hole, and then a planarizing process such as CMP process is conducted to remove part of the metals for forming a contact plug or metal interconnection 60 in the contact hole electrically connecting the top electrodes 50 underneath. Next, a stop layer 62 is formed on the IMD layer 58. Preferably, the stop layer 62 is made of nitrogen doped carbide (NDC), silicon nitride, silicon carbon nitride (SiCN), silicon oxynitride (SiON), or combination thereof.

Next, another IMD layer 64 is formed on the surface of the stop layer 62 and one or more photo-etching process is conducted to remove part of the IMD layer 64 and part of the stop layer 62 to form contact holes (not shown). Next, conductive materials are deposited into the contact holes and a planarizing process such as CMP is conducted to form a metal interconnection 66 connecting the top electrode 50 and metal interconnection 60 underneath, and another stop layer 72 is formed on the surface of the metal interconnections 66 thereafter. Similar to the aforementioned metal interconnection 60, the metal interconnections 66 could be embedded within the IMD layer 64 according to a single damascene process or dual damascene process. For instance, the metal interconnection 66 could further include via conductors 68 connecting the metal interconnection 60 underneath and a trench conductor 70 atop the via conductors 68. Moreover, the metal interconnection 66 could further include a barrier layer and a metal layer, in which the barrier layer could be selected from the group consisting of titanium (Ti), titanium nitride (TiN), tantalum (Ta), and tantalum nitride (TaN) and the metal layer could be selected from the group consisting of tungsten (W), copper (Cu), aluminum (Al), titanium aluminide (TiAl), and cobalt tungsten phosphide (CoWP).

Overall, the present invention discloses a MRAM device and fabrication method thereof, which first forms a stop layer 74 on the IMD layer and metal interconnection, patterns the stop layer to form an opening, forms a bottom electrode 42 made of TiN in the opening, planarizes part of the bottom electrode so the top surface of the bottom electrode is even with the top surface of the stop layer, forms a MRJ stack on the bottom electrode and stop layer, and then patterns the MTJ stack to form a MTJ.

In conventional approaches, when the bottom electrode typically made of tantalum is patterned together with the MTJ stack to form the MTJ, tantalum metal tends to be sputtered and redeposited on the sidewalls of the MTJ due to the shadow effect. To resolve this issue, the bottom electrode 42 with a narrower line width is embedded within the stop layer 74 in advance according to FIGS. 1-7 of the present invention. As a result, during the subsequent patterning of the MTJ stack, only the stop layer is etched and leaving the bottom electrode unaffected. This approach ensures the overall performance and integrity of the resulting MTJ.

Furthermore, in accordance with the embodiments illustrated in FIGS. 8-12, the present invention provides a method whereby, during the formation of metal interconnections 30 and 32, a barrier layer is first extended to fully cover the surface of the IMD layer. Thereafter, a portion of the metal layer 36 is removed using chemical mechanical polishing (CMP) and etching back process such that the top surfaces of the metal layer 36 and the barrier layer 34 are substantially level and slightly higher than the top surface of the IMD layer. A MTJ stack is then formed over the resulting structure, and both the MTJ stack and the barrier layer are patterned together to form the MTJ. Through this approach, the sidewalls of the MTJ are aligned with and extend along the sidewalls of the barrier layer on the IMD layer. This effectively mitigates the issue of metal atom redeposition caused by the shadow effect during MTJ patterning, which can otherwise result in contamination of the MTJ sidewalls or the sidewalls of the underlying metal interconnects.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming a first inter-metal dielectric (IMD) layer on a substrate;
forming a metal interconnection in the first IMD layer;
forming a stop layer on the first IMD layer;
patterning to stop layer to form an opening;
forming a bottom electrode (BE) in the opening;
forming a magnetic tunneling junction (MTJ) stack on the BE; and
patterning the MTJ stack to form a MTJ.

2. The method of claim 1, further comprising:
forming the BE on the stop layer and into the opening; and
planarizing the BE.

3. The method of claim 1, further comprising:
removing part of the MTJ stack, part of the stop layer, and part of the first IMD layer to form the MTJ;
forming a cap layer on the MTJ; and
forming a second IMD layer around the cap layer.

4. The method of claim 1, wherein a width of the BE is less than a width of the metal interconnection.

5. The method of claim 1, wherein a width of the BE is less than a width of the MTJ.

6. The method of claim 1, wherein sidewalls of the MTJ and the stop layer are aligned.

7. A semiconductor device, comprising:
a first inter-metal dielectric (IMD) layer on a substrate;
a metal interconnection in the first IMD layer;
a bottom electrode (BE) on the metal interconnection;
a stop layer on sidewalls of the BE; and
a magnetic tunneling junction (MTJ) on the BE and the stop layer.

8. The semiconductor device of claim 7, further comprising:
a cap layer adjacent to the MTJ and the stop layer; and
a second IMD layer around the cap layer.

9. The semiconductor device of claim 7, wherein a width of the BE is less than a width of the metal interconnection.

10. The semiconductor device of claim 7, wherein a width of the BE is less than a width of the MTJ.

11. The semiconductor device of claim 7, wherein sidewalls of the MTJ and the stop layer are aligned.
